(19) United States
(12) Patent Application Publication
(10) Pub. No.: US 2006/0020412 A1
(43) Pub. Date: Jan. 26, 2006

(54) Analog waveform information from binary sampled measurements

(76) Inventor: Matthew M. Bruensteiner, San Jose, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/897,539

(22) Filed: Jul. 23, 2004

(51) Int. Cl. G01R 27/28

(52) U.S. Cl. 702/117

(57) ABSTRACT

Circuits that count zeros or ones in a binary sampling of a signal can measure analog characteristics of the signal. By this technique, relatively simple circuits can perform parameter measurements that are difficult to achieve with BER-based binary sampling techniques. Low cost binary sampling circuits can also perform measurements that previously might have required more complex and expensive analog sampling. The new technique is applicable to full-featured test systems, low-cost test circuits, and on-chip test circuits.

### BACKGROUND

Binary sampling commonly refers to periodically sampling a signal to reduce the signal to a time-indexed series of binary values (0 or 1). In contrast, analog sampling such as commonly used in oscilloscopes generally samples a signal less frequently, but each sample retains information about the analog level of the signal when sampled. The analog level for each sample can be recorded as a multi-bit digital value, in which case, analog sampling generates a series of multi-bit values that approximates the analog signal.

An advantage of binary sampling is that binary sampling can generally achieve a higher sampling rate than can be practically achieved with analog sampling. For example, a binary sampling instrument, such as a bit error rate tester (BERT), can sample every bit of a high data rate signal, while current analog samplers with analog bandwidths over a couple of GHz are generally limited to a few thousand samples per second. Analog samplers can thus capture only a small fraction of the bits of a high data rate signal.

Another benefit of binary sampling is that a binary sampling circuit for a given test signal data rate can often be manufactured at a lower cost than an analog sampling circuit suitable for measurement of the signal. The lower cost of binary sampling makes it desirable to try to replicate the capabilities of analog sampling systems using binary sampling systems.

### SUMMARY

In accordance with an aspect of the invention, a binary sampling system can sample a signal to generate test data that is analyzed to extract information about the analog characteristics of the signal. For example, a bit error tester or alternatively a counter counting the number of samples having a particular value can measure the percentages or rates of zeros or ones measured in a signal for a range of sampling thresholds and a range of phase offsets. Derivatives of the measured rate then indicate the density of signal waveforms at the voltage and phase at which the derivative was taken, and plots of the derivative provide similar information to that provided in an oscilloscope trace.

One specific embodiment of the invention is a test system that includes an analog comparator, a binary sampler, and a counter. The analog comparator compares an input signal to an adjustable threshold level. The binary sampler, which uses an adjustable phase parameter that determines a phase of sampling, samples an output signal from the analog comparator. The counter can then count samples from the binary sampler that have a selected binary state. A processing system can then be used to analyze a set of counts/rates from the counter to determine an analog characteristic of the input signal. The analysis can include, for example, taking a derivative or identifying a threshold corresponding to a characteristic voltage of the signal.

Another specific embodiment of the invention is a method for analyzing a signal. The method includes: varying a threshold over a first range; varying a phase over a second range; and for each value of the threshold and the phase, determining a rate at which the signal has a voltage above the threshold when sampled at the phase. Analysis of the rates can then determine an analog characteristic of the signal.

Yet another specific embodiment of the invention is another method for analyzing a signal. The method includes sampling the signal with a binary sampler having an adjustable phase for sampling and an adjustable threshold. The adjustable threshold separates levels of the signal corresponding to different binary states of samples output from the binary sampler. From the sampling, the method determines rates of a selected one of the binary states in the samples output from the binary sampler. Each of the rates is preferably determined for a unique combination of values of the adjustable threshold and the adjustable phase. The rates can then be analyzed to determine an analog characteristic of the signal.

### BRIEF DESCRIPTION OF THE DRAWINGS

FIG. 1 is a block diagram of a system using binary sampling and bit error rate measurements to determine analog characteristics of a signal.

FIG. 2 is a block diagram of a system in accordance with an embodiment of the invention using binary sampling and value counts to determine analog characteristics of a signal.

FIG. 3 is a block diagram of a delay circuit that provides clock signal with an adjustable phase delay.

FIG. 4 is a plot illustrating how the rate of zero values represented in a signal depends on the threshold level separating voltages representing zero from voltages representing one when a phase for sampling is within the rise time or the fall time of the signal.

FIG. 5 illustrates how the rate of occurrences of zeros in a data signal depends on the threshold level separating voltages representing zero from voltages representing one.

FIG. 6 shows how a derivative of the rate shown in FIG. 5 provides traces that indicate analog characteristics of a signal.

Use of the same reference symbols in different figures indicates similar or identical items.

### DETAILED DESCRIPTION

In accordance with an aspect of the invention, a binary sampling system can analyze analog characteristics of high-frequency or high-data rate signals. For the analysis, the binary sampling system determines the rate of samples having a voltage level above or alternatively below a threshold level (e.g., a rate of samples having value one or zero) for a specific phase of the signal). The rate measurement is then repeated for a range of threshold levels and phases to determine the rate as a function of the threshold (i.e., voltage) and the phase (i.e., time). A derivative of the rate function indicates the density of occurrences of the signal within the ranges of voltage and time and therefore when plotted simulates traces generated in an oscilloscope. The analog characteristics of the signal can thus be determined from the binary sampling.

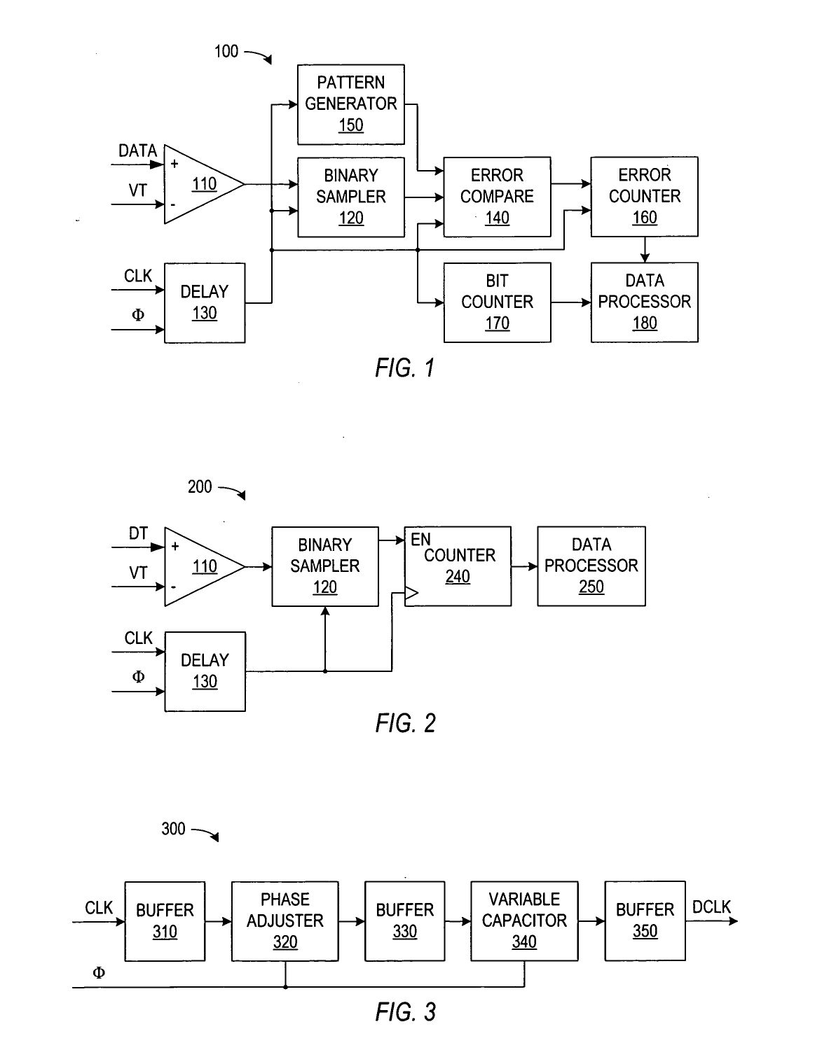

In a related measurement process, binary sampling techniques based on bit error ratio (BER) measurements determine analog characteristics of a signal such as a data signal from a system under test (SUT). FIG. 1 illustrates a system 100 using BER-based techniques to measure analog characteristics of a SUT (not shown). System 100 includes a differential amplifier or comparator 110, a binary sampler 120, a variable delay circuit 130, an error compare circuit 140, a pattern generator 150, an error counter 160, and a bit counter 170.

During a measurement, the system under test produces a signal DATA representing a known series of binary values, and signal DATA is input to comparator 110. Comparator 110 compares the analog voltage of signal DATA to a threshold level VT, and generates an output signal that is at a high voltage or a low voltage depending on whether the analog voltage of signal DATA is higher or lower than the threshold level VT.

A binary sampler 120 samples the output signal from comparator 110 and produces a binary sampled signal having a data frequency that is preferably the same as the data frequency of signal DATA. Alternatively, the data frequency of signal DATA could be an integer multiple of the sampling frequency that binary sampler 120 uses. To control the timing of sampling in the embodiment of FIG. 1, a variable delay circuit 130 receives a clock signal CLK having the desired frequency, and delays clock signal CLK by a delay that a parameter Φ selects. The delayed clock signal triggers binary sampler 120 and thereby controls the frequency and the phase at which binary sampler 120 samples the output signal from comparator 110.

Error compare circuit 140 compares the binary sampled signal from sampler 120 to a binary signal from pattern generator 150. The binary signal from pattern generator 150 represents a data series that is the same as or derived from the known binary series that signal DATA should represent. A difference between the binary sample from sampler 120 and the known signal from pattern generator 150 indicates a bit error in signal DATA for the parameters VT and Φ used. Error compare circuit 140 triggers error counter 160 to count the errors, and the clock signal (or the delayed clock signal) triggers bit counter 170 to count the total number of bits sampled. The ratio of the error count from counter 160 to the bit count from bit counter 170 indicates the bit error ratio (BER).

A processing system 180 analyzes the BERs that are measured for a range of threshold levels VT and clock phases Φ. Observing the variation in the BER as the threshold level VT and the sampling phase Φ vary indicates analog characteristics of signal data. For example, when sampling phase Φ corresponds to a time when signal DATA may transition between a low level (e.g., binary zero) and a high level (e.g., binary one), the BER changes dramatically as comparison threshold level VT crosses the characteristic voltage levels of signal DATA at the sampled phase. Analog voltage levels of signal DATA can thus be determined at a series of values of phase Φ to provide information similar to that provided in an oscilloscope trace.

The analysis techniques available in system 100 as described above use a signal DATA that represents a known binary series, which permits identification of errors and measurement of the BER. Accordingly, such analysis techniques may not be available during normal operation of the system under test when the values of signal DATA are not known.

FIG. 2 illustrates a system 200 in accordance with an embodiment of the invention that can measure analog characteristics of a signal DT without knowing a specific series of bits represented in signal DT. System 200 includes a differential amplifier or comparator 110, a binary sampler 120, a variable delay circuit 130, a counter 240, and a data processor 250. When compared to system 100, system 200 does not require a pattern generator or an error comparator that are in the BER-based system 100 described above. In alternative embodiments, system 200 can be implemented in a full-featured test system, a low-cost test circuit for circuit self-testing, or an on-chip test circuit for chip self testing. In one specific embodiment, system 200 is a low cost test circuit implemented as a printed circuit assembly.

In operation, system 200 can determine a count or rate of samples of a signal DT having a voltage below (or alternatively above) a selected threshold level VT at a selected phase Φ of signal DT. In particular, comparator 110 compares voltage of signal DT to the threshold level VT and drives an output signal high or low depending on whether signal DT has a voltage higher or lower than threshold level VT. Binary sampler 120 samples the output signal from comparator 110 at frequency that preferably corresponds to the data rate of signal DT and a phase that the parameter Φ of variable delay 130 selects. The output signal of sampler 120 enables or disables counter 240, so that counter 240 counts when the binary samples are zero or one (corresponding to signal DT being below or above threshold level VT).

System 200 can be implemented using well-known devices. For example, in an exemplary embodiment of the invention, comparator 110 is a differential amplifier, and binary sampler 120 is a high speed D flip-flop. If desired, a demultiplexer circuit (not shown) may be included following binary sampler 120 and effectively convert a high frequency bit stream from binary sampler 120 to a lower frequency parallel data stream. Several lower-speed circuits operating in parallel could then implement counter 240 and parts of data processor 250.

Delay circuit 130 preferably provides precisely controlled delays to permit phase adjustments in signal DT that may have a frequency greater than 1 GHz. FIG. 3 illustrates one embodiment of a suitable delay circuit 300. Delay circuit 300 includes a buffer 310 that relays and input clock signal CLK to a phase adjustor 320. Phase adjuster 320 provides larger scale adjustments of the phase that parameter Φ selects and can be implemented using a commercially available phase adjustor such as an MC100EP195 from ON Semiconductor, Inc. To provide finer phase control, a second buffer 330 feeds the signal from phase adjustor 320 to circuit block 340 that provides a variable capacitance. Circuit block 340 may include, for example, one or more varactor diodes that provide a capacitance that slows transitions in the signal by an amount that depends on parameter Φ. A final buffer 350 drives the delayed clock signal DCLK high or low at times that depend on the transition rate of the signal from circuit block 340.

Data processor 250 performs analysis processes that are described further below. In alternative embodiments of the invention, data processor 250 can be implemented in dedicated hardware, firmware executed in a microcontroller, and/or software executed in a computer or other external system.

System 200 of FIG. 2 does not compare the sampler output to a known waveform but instead counts the number of zeros (or ones) in a signal DT representing unknown data values. System 200 thus uses binary sampling, but not a bit error rate measurement. However, a BER test circuit measurement can determine the rate of zeroes (or of ones) if the “expected” signal generated by pattern generator 150 is all ones (zeroes). Thus, analysis techniques described below may be applied either when sampling circuit 200 or a BER test circuit is available. However, in normal operation, the BER test system must maintain synchronization between a local pattern generator and the input signal because a BER test system compares an input signal to an expected pattern. Therefore many BER circuits are designed to enter a synchronization search mode when the BER is high, for example, when the BER is above about 0.1. In order for a BER tester to be able to reproduce all capabilities of test system 200, the BER tester must permit disabling of the synchronization search mode. Test system 200, in contrast, does not require pattern synchronization. Therefore, system 200 can operate even when sampling conditions would produce a high BER. The ability to test signals even in high BER regions may allow certain analyses that are not possible with unmodified BER test systems. For example, signal properties such as rise-time, fall-time, average 1-level, average 0-level, maximum voltage, mask test outside the eye-center, overshoot or 1-level ripple, undershoot or 0-level ripple can be measured or determined.

In an exemplary embodiment, the count in counter 240 of system 200 is proportional to the rate (sometimes referred to herein as the zero-rate) of occurrences of signal DT being below threshold level VT at the selected phase Φ of signal DT. System 200 can determine comparable zero-rates for other threshold levels and phases by setting the desired parameters VT and Φ and counting zeros for a fixed time. Alternatively, the zero-rate is equal to the ratio of the count from counter 240 and a matching count of the total number of bits. A similar one-rate is proportional to a count of the number of samples above threshold level VT, and the sum of the one-rate and the zero-rate should be equal to the bit rate or frequency of signal DT. In accordance with an aspect of the invention, analog characteristics of a signal can be extracted from zero-rates or one-rates found by binary sampling of the signal using a ranges of phases and thresholds. The following describes examples of using the zero-rates in binary sampling to determine analog characteristics of a signal, but one-rates could be used in a similar manner.

FIG. 4 illustrates a plot 400 of zero rates as a function of the threshold level VT at a fixed sampling phase that sometimes corresponds to signal DT transitioning between a high level and a low level. Plot 400 illustrates that the zero-rate is zero when the threshold level VT is below a minimum voltage of V0_{MIN} of signal DT because all samples have voltage greater than or equal to voltage V0_{MIN}. As threshold level VT increases from the minimum voltage V0_{MIN} to a maximum voltage V0_{MAX} of the voltages representing bit value zero, the rate increases, and then plateaus at a rate 410 corresponding to the probability of signal DT remaining stable at bit value zero for two consecutive bits. In a typical data signal that has a statistically equal chance of retaining or switching binary value, the first plateau rate 410 will be about 25%, which corresponds to the chance of two consecutive bits having value zero. However, for a binary series having other statistical properties, the level of the first plateau rate 410 may not correspond to 25%.

The selected phase for plot 400 is close to transitions between consecutive bits. In particular, at the selected phase, the average voltage when the signal is rising is voltage VR_{AVE}, and the average voltage when the signal is falling is voltage VF_{AVE}. Plot 400 illustrates the case when the selected phase is early in the rise or fall so that the average rising voltage VR_{AVE} is less than the average falling voltage VF_{AVE}.

As the threshold VT approaches the average rising voltage VR_{AVE}, the zero-rate increases as more of the cases of voltage rise become less than threshold level VT. A second plateau rate 420 occurs when nearly all samples of the rising voltage at the selected phase are less than the threshold level VT. This plateau rate would correspond to about 50% for a signal representing a binary series in which the probability of value zero is 50%, but plateau rate 420 may not correspond to 50% for a signal having different statistical properties.

Similarly, as the threshold level VT approaches the average falling voltage VF_{AVE}, the zero-rate increases as more of the cases of voltage fall become less than threshold level VT. A third plateau rate 430 occurs when nearly all samples of the falling voltage at the selected phase are less than the threshold level VT. This plateau rate 430 would be about 75% for a signal representing a binary series in which the probability to remain at the same level is equal to the probability to transition to the other level, but plateau rate 430 may differ if the signal has different statistical properties.

The zero-rate rises again when the threshold level VT exceeds the minimum voltage V1_{MIN} representing binary value 1. A final plateau rate 440 of 100% occurs when the threshold level VT is greater than the maximum voltage V1_{MAX} of signal DT.

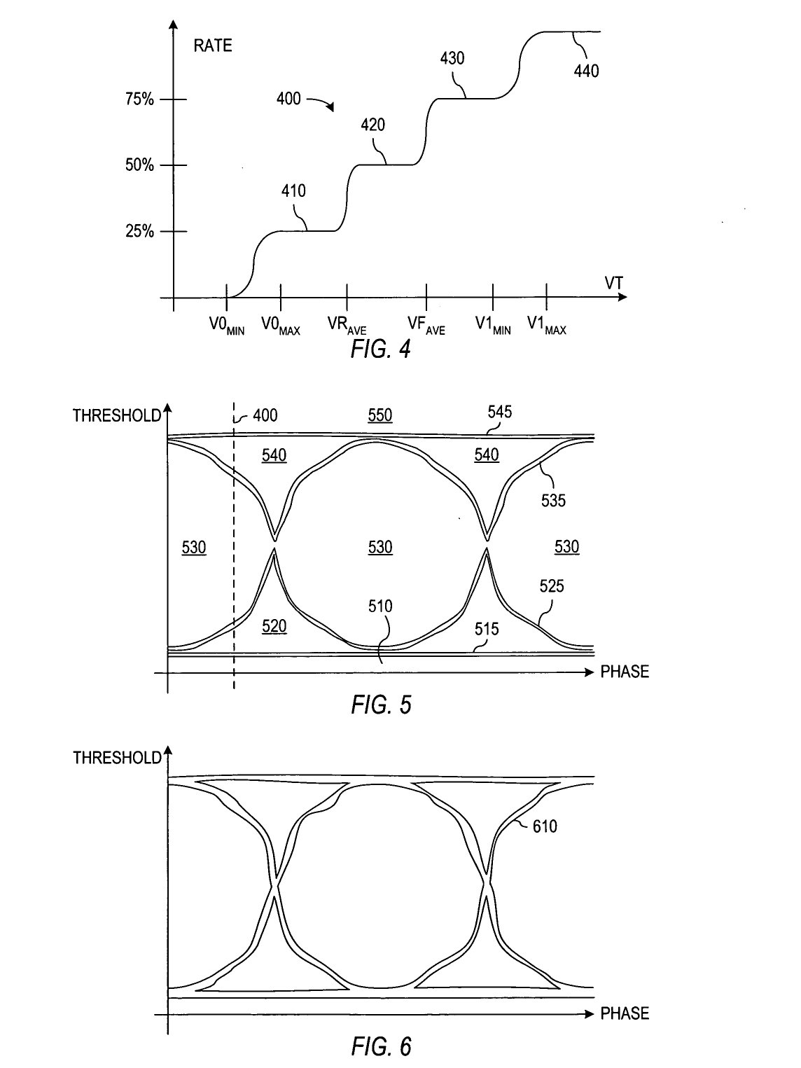

Varying the selected phase and repeating the measurements of the rates for each of a series of threshold levels VT provides the zero-rate as a function of a two-dimensional domain. FIG. 5 illustrates how the domain of threshold level VT and phase Φ can be divided into regions 510, 520, 530, 540, and 550. Region 510 corresponds to a zero-rate that is nearly zero because the threshold voltage VT is below the minimum voltage of the signal. Region 520 corresponds to a first plateau rate where threshold level VT is greater than nearly all of the cases where the sample corresponds to a stable low level of the signal. Region 530 corresponds to a second plateau rate where threshold level VT is greater than one of the average transitional voltages of the signal. Region 540 corresponds to a third plateau rate where threshold level VT is greater than both of the average transitional voltages of the signal. Region 550 corresponds to the final plateau where threshold level VT is greater than maximum voltage of the signal. Regions 515, 525, 535, and 545 are regions where the rate is transitioning from one plateau to another.

Processing of the data represented in FIG. 5 can provide a result comparable to an oscilloscope measurement. For example, if at a given sampling phase, a zero-rate of 50% is observed at a threshold V1 and a zero-rate of 51% is observed at a threshold V2 that is greater than threshold V1, then 1% of the sampled signal waveforms must have had voltages between V1 and V2 at the sampling time/phase. More generally, the density of traces per voltage of the signal, which is what an oscilloscope measures, is equal to the derivative of the zero-rate with respect to sampling threshold. Given a set of zero-rates that a binary sampler produced at various choices of parameters Φ and VT, well-known numerical techniques can approximate the derivative. In particular, finite differences in the rates provide a simple approximation of the derivative. Numerical derivatives are inherently noisy, and thus long sampling times may be preferred to obtain high accuracy in estimating the trace density.

FIG. 6 illustrates areas 610 of the domain of threshold level VT and phase Φ where the derivative of the rate function is above a minimal non-zero level. Areas 610 correspond to oscilloscope traces. In particular, areas 610 form the “eye” pattern that oscilloscopes traces conventionally form during analysis a binary signal. The eye pattern presents analog characteristics of the signal such as the minimum and maximum voltage level representing zero, the minimum and maximum voltage levels representing one, the rising edge duration, the falling edge duration, and the general time dependence of the rise and fall of voltage levels. (Rising and falling edge durations are signal parameters representing the time required for transitions between binary zero and one levels.) Given the trace density eye, such as that shown in FIG. 6, the rise and fall times can be measured using techniques developed for oscilloscope analysis. Further refinements to the analysis techniques, which reduce the amount of sample data required, are described further below.

The measurement results illustrated in FIG. 6 depend only on the derivative or gradient of the zero-rates (or the one-rates), and no knowledge of the incoming pattern or binary series is required. Thus, the technique may be applied to operational systems. Further, a system measuring analog signal characteristics through evaluation of the zero-rate (or one-rate) of a binary sampled signal can employ circuitry that is simpler than a BER tester. For example, a system such as system 200 of FIG. 2 that can measure zero-rates (or one-rates) does not require the error comparator and local pattern generator used in the bit error measurement systems such as system 100 of FIG. 1.

An advantage of using zero-rates or one-rates for signal analysis is the ability to determine voltages Vtop and Vbase, which represent the average voltages of respective binary values one and zero. Oscilloscopes commonly provide built-in measurements of voltages Vtop and Vbase, but such measurements may be impractical when using BER testers due to the synchronization requirements between the sampled signal and the known pattern. Using zero-counting or one-counting, voltages Vtop and Vbase can be measured by choosing a sampling phase at the eye center of traces 610 and locating the threshold level VT giving 75% and 25% zero-rate, respectively. It should be noted that the analysis that determines voltages Vtop and Vbase does not require determination of a derivative or the trace density.

The 20%-80% rising edge duration can be determined using voltages Vtop and Vbase that are determined as described above. A process for determining the 20%-80% rising edge duration, for example, can initially set threshold level VT to 0.8*Vbase+0.2*Vtop, and then search for a phase Φ to the right of the eye center that gives a zero-rate equal to ½ of the plateau rate 410. Subtracting the bit period from this phase Φ provides the initial instant tr1 of the rising edge. The process can then set threshold level VT to 0.2*Vbase+0.8*Vtop and search for a phase Φ to the left of eye center that achieves a zero-rate equal to the average of plateau rate 430 and plateau rate 440. This identifies the final instant tr2 of the rising edge. The rising edge duration is the difference tr2−tr1. Other VT values might be used, for example to find the 10%-90% rising edge duration. It is also straightforward to modify the described process to find similar falling edge durations. The method of searching for the correct zero-rate could be by any of several well-known search algorithms. The use of search algorithms, and direct analysis of the zero-rate without calculating derivatives, reduces the number of combinations of phase Φ and threshold level VT that must be sampled to reach the desired measurement result.

Another measurable analog signal characteristic is overshoot or undershoot. Overshoot and undershoot are signal parameters that indicate the amount of ringing present in a waveform. Because ringing phenomena are characterized by waveform behavior outside the central eye area, measurement overshoot and undershoot by BER techniques may not be practical, but zero or one counting techniques can measure these parameters. For example, to measure overshoot, the system can measure Vtop at various phases Φ. The number of different phases measured can be selected according to the bandwidth of the signal DT. The maximum Vtop, divided by Vtop at the center phase, is the overshoot.

Mask testing is a further use of both oscilloscopes and BER testers. Mask testing requires detection of signal traces passing through forbidden regions of the eye. BER testers generally are able to test only masks within the central eye region. The masks specified for important communications standards such as Gigabit Ethernet and Fibre Channel also specify mask regions above and below the eye. Testing against these masks is commonly done with an oscilloscope. However, zero or one counting allows testing mask regions inside and outside the central eye area using low cost binary sampling circuits. A system having a zero or one-counter can test above or below the central eye simply by setting parameters VT and Φ to correspond to points in the mask region above (or below) the eye, and count occurrences of ones (or zeroes), which indicate mask failures.

Although the invention has been described with reference to particular embodiments, the description is only an example of the invention's application and should not be taken as a limitation. For example, although the above-described embodiments have concentrated on analysis of binary data signals, similar techniques and circuit can analyze other signals such as clock signal, a return-to-zero encoded data signal, or a multilevel-encoded data signal. Various other adaptations and combinations of features of the embodiments disclosed are within the scope of the invention as defined by the following claims.

What is claimed is:

1. A test system comprising:
an analog comparator connected to compare an input signal to an adjustable threshold level;
a binary sampler connected to sample an output signal from the analog comparator, wherein the binary sampler has an adjustable phase that determines a phase of the signal that is sampled; and
a counter connected to count samples from the binary sampler that have a selected binary state.

2. The system of claim 1, further comprising a processing system connected to analyze a set of count values from the counter to determine an analog characteristic of the input signal.

3. The system of claim 2, wherein the processing system determines an average voltage representing a binary value by identifying a level of the adjustable threshold that provides a count representing a target rate of occurrence of the selected binary state.

4. The system of claim 2, wherein the processing system analyzes a set of measured counts corresponding to a range of adjustable threshold level and a range of the adjustable phase to generate a representation of time dependence of an analog voltage of the input signal.

5. The system of claim 4, wherein the input signal is a binary signal, and the representation comprises an eye pattern indicating rising and falling edges of the input signal.

6. The system of claim 4, wherein the processing system determines a derivative of the measured counts.

7. The system of claim 1, wherein the input signal has a pattern that is unknown in the test system.

8. The system of claim 7, wherein the input signal represents a series of binary values having a pattern that is unknown in the test system.

9. A method for determining analog properties of a signal, comprising:
varying a threshold over a first range;
varying a phase over a second range;
for each value of the threshold and the phase, determining a rate at which the signal has a voltage above the threshold when sampled at the phase; and
analyzing the rates to determine an analog characteristic of the signal.

10. The method of claim 9, wherein analyzing the rates comprises determining an average voltage representing a binary value of the signal by identifying a level of the threshold that provides a target rate of occurrences of the voltage being above the threshold when sampled.

11. The method of claim 9, wherein analyzing the rates comprises generating a representation of time dependence of an analog voltage of the signal.

12. The method of claim 11, wherein the signal is a binary signal, and the representation comprises an eye pattern indicating rising and falling edges of the input signal.

13. The method of claim 11, wherein analyzing the rates comprises determining a derivative of the rates with respect to the adjustable threshold.

14. A method for analyzing a signal, comprising:
sampling the signal with a binary sampler having an adjustable phase for sampling and an adjustable threshold, wherein the adjustable threshold separates levels of the signal corresponding to different binary states of samples output from the binary sampler;
determining rates of a selected one of the binary states in the samples output from the binary sampler, each of the rates being determined for a unique combination of values of the adjustable threshold and the adjustable phase; and
analyzing the rates to determine an analog characteristic of the signal.

15. The method of claim 14, wherein analyzing the rates comprises determining an average voltage representing a binary value of the signal by identifying a level of the adjustable threshold that provides a target rate of occurrences of the selected binary state.

16. The method of claim 14, wherein analyzing the rates comprises generating a representation of time dependence of an analog voltage of the signal.

17. The method of claim 16, wherein the signal is a binary signal, and the representation comprises an eye pattern indicating rising and falling edges of the input signal.

18. The method of claim 16, wherein analyzing the rates comprises determining a derivative of the rates with respect to the adjustable threshold.
